(19) United States
(12) Patent Application Publication
(10) Pub. No.: US 2026/0012163 A1
(43) Pub. Date: Jan. 8, 2026

(54) FEEDBACK LINEARIZED FREQUENCY CONVERTER FOR SCALABLE LO PHASED ARRAYS

(71) Applicant: The Regents of the University of California, Oakland, CA (US)

(72) Inventors: Jonathan Tao, Santa Barbara, CA (US); James Buckwalter, Santa Barbara, CA (US)

(21) Appl. No.: 19/072,485

(22) Filed: Mar. 6, 2025

Related U.S. Application Data
(60) Provisional application No. 63/667,418, filed on Jul. 3, 2024.

(51) Int. Cl. H03K 5/00

(52) U.S. Cl. CPC H03K 5/00006

(57) ABSTRACT

A frequency conversion system can include a conversion circuit that generates an output signal at a different frequency from an input signal. A power detection circuit can monitor characteristics of the input or output signal and produce a control signal. A feedback control circuit can dynamically adjust a bias signal in response to the control signal, regulating conversion gain by reducing power consumption when output power increases and maintaining stability when output power decreases. This adaptive feedback mechanism can improve efficiency, scalability, and performance while enabling real-time adaptation to changing signal conditions.

### RELATED APPLICATIONS

This application claims the benefit of U.S. Provisional Patent Application No. 63/667,418, filed on Jul. 3, 2024, entitled “Feedback Linearized Frequency Multiplier Circuit For Scalable Local-Oscillator Phased Arrays,” which is hereby incorporated herein by reference.

### STATEMENT OF GOVERNMENT SUPPORT

This invention was made with government support under Grant No. HR0011-23-3-0002 awarded by the Department of Defense/Defense Advanced Research Projects Agency (DARPA). The government has certain rights in the invention.

### FIELD

The present disclosure generally relates to electronic circuits and, more particularly, to frequency conversion circuits used in local oscillator phased array systems for millimeter-wave frequencies.

### BACKGROUND

Phased array systems are widely used in radar, communications, and imaging, particularly at millimeter-wave frequencies above 100 GHz. These systems rely on local oscillator (LO) signals for frequency conversion, often generated by frequency converters (e.g., multipliers, mixers, dividers, or PLLs). However, conventional frequency multiplier circuits exhibit non-linear characteristics, making it difficult to maintain consistent control over output power and frequency conversion gain. This non-linearity causes variations in input power to produce unpredictable output power, leading to inefficiencies such as constant power consumption regardless of performance needs. Such limitations hinder power optimization, especially in mobile or power-constrained applications, where adaptive control over power consumption is essential for efficiency and scalability.

### SUMMARY

Certain illustrative examples are described in the following numbered clauses:

Clause 1. A frequency conversion system, comprising:
a conversion circuit configured to receive an input signal and a bias signal, and to generate an output signal at a different frequency than the input signal, the output signal having an output power;
a power detection circuit electrically coupled to the conversion circuit and configured to produce a control signal based on at least one characteristic of the input signal or the output signal; and
a feedback control circuit configured to adjust the bias signal based on the control signal,
wherein the feedback control circuit dynamically varies the bias signal such that the output power of the conversion circuit is regulated by decreasing a conversion gain of the conversion circuit when the output power increases and by increasing the conversion gain of the conversion circuit when the output power decreases.

Clause 2. The frequency conversion system of any of the preceding clauses, wherein the conversion circuit comprises a pair of transistors configured in a push-pull topology, wherein the power detection circuit comprises a transistor having an emitter coupled to collectors of the pair of transistors, and a bias resistor connected between a collector and a base of the transistor; and wherein the feedback control circuit comprises a feedback resistor connected to the collectors of the pair of transistors and an inductor coupled to an input port of the conversion circuit.

Clause 3. The frequency conversion system of any of the preceding clauses, wherein the power detection circuit is configured to modulate the control signal based on at least one characteristic of the input signal, wherein the at least one characteristic of the input signal comprises input power level, input frequency, input amplitude, or input phase.

Clause 4. The frequency conversion system of any of the preceding clauses, wherein the power detection circuit is configured to modulate the control signal based on at least one characteristic of the output signal, wherein the at least one characteristic of the output signal comprises output power level, output frequency, output amplitude, or output phase.

Clause 5. The frequency conversion system of any of the preceding clauses, wherein the power detection circuit comprises a transistor configured to detect changes in the output power of the conversion circuit and to generate the control signal in response to the changes in the output power.

Clause 6. The frequency conversion system of any of the preceding clauses, wherein the feedback control circuit is configured to maintain a substantially linear relationship between input signal power and the output signal power over a defined operating range.

Clause 7. The frequency conversion system of any of the preceding clauses, wherein the feedback control circuit is configured to dynamically adjust the bias signal in real time based on instantaneous variations in the output power.

Clause 8. The frequency conversion system of any of the preceding clauses, wherein the conversion circuit further comprises a pair of transistors arranged to generate a fourth harmonic of the input signal in a push-pull multiplier stage.

Clause 9. The frequency conversion system of any of the preceding clauses, wherein the conversion circuit includes a pair of transistors in a push-pull topology, and wherein the bias signal is applied to bases of the pair of transistors to regulate conduction cycles and control conversion gain.

Clause 10. The frequency conversion system of any of the preceding clauses, wherein the conversion circuit comprises at least one of a Gilbert cell topology, a differential pair topology, a push-push topology, a cascode amplifier topology, a cross-coupled transistor pair topology, a common-base amplifier topology, a common-emitter amplifier topology, a single-ended resonant tank topology, a differential amplifier topology, a distributed amplifier topology, or a phase-locked loop (PLL) topology.

Clause 11. A method of adaptively controlling a bias signal in a frequency multiplier circuit, the method comprising:
receiving, by a feedback control circuit, a control signal from a power detection circuit, wherein the control signal is based on at least one characteristic of an input signal or an output signal of the frequency conversion circuit;
generating, by the feedback control circuit, a dynamically adjustable bias signal in response to the control signal; and
applying the bias signal to the frequency conversion circuit, wherein the bias signal:
decreases in response to an increase in output power of the frequency conversion circuit, thereby reducing power consumption and gain variation; and
increases in response to a decrease in output power of the frequency conversion circuit, thereby maintaining a stable frequency conversion gain.

Clause 12. The method of clause 11, wherein the control signal is generated by detecting a rectified current component in the frequency conversion circuit, the rectified current component being indicative of output power variations.

Clause 13. The method of clause 11, wherein the feedback control circuit comprises a feedback resistor connected between a collector node of the frequency conversion circuit and a bias node, the feedback resistor adapting a conduction cycle of the multiplier transistors in response to changes in output power.

Clause 14. The method of clause 11, wherein the feedback control circuit regulates the bias signal to maintain a substantially constant transconductance in the frequency conversion circuit across a range of input power levels.

Clause 15. The method of clause 11, wherein the power detection circuit comprises a transistor configured in a common-base topology, the transistor generating the control signal based on variations in collector current from the frequency conversion circuit.

Clause 16. A feedback control circuit for a frequency conversion system, comprising:
a control input node configured to receive a control signal from a power detection circuit, the control signal being indicative of at least one characteristic of an input signal or an output signal of a frequency multiplier circuit;
a bias generation module configured to generate a dynamically adjustable bias signal in response to the control signal; and
a bias output node configured to provide the dynamically adjustable bias signal to the frequency multiplier circuit,
wherein the bias generation module is configured to reduce the bias signal in response to an increase in output power of the frequency multiplier circuit to compensate for gain variation and reduce power consumption, and wherein the bias generation module is configured to increase the bias signal in response to a decrease in output power of the frequency multiplier circuit to maintain a substantially stable frequency conversion gain across varying operating conditions.

Clause 17. The feedback control circuit of clause 16, wherein the bias generation module comprises a feedback resistor coupled between a collector node of the frequency multiplier circuit and a bias node, the feedback resistor being configured to adjust the conduction cycle of the multiplier transistors in response to variations in the control signal.

Clause 18. The feedback control circuit of clause 16, wherein the control signal is generated based on a rectified current component detected in the frequency multiplier circuit, the rectified current being indicative of output power variations.

Clause 19. The feedback control circuit of clause 16, wherein the bias generation module is configured to adjust the bias signal in real time to maintain a substantially linear relationship between input signal power and output signal power over a dynamic operating range.

### BRIEF DESCRIPTION OF THE DRAWINGS

Throughout the drawings, reference numbers can be re-used to indicate correspondence between referenced elements. The drawings are provided to illustrate embodiments of the present disclosure and do not limit the scope thereof.

FIG. 1 illustrates an example of an adaptive frequency conversion system.

FIGS. 2A-2D illustrate various examples of adaptive frequency conversion systems.

FIG. 3 illustrates an example of harmonic generation in a push-pull frequency multiplier.

FIG. 4 illustrates an example of the effect of bias feedback in an adaptive frequency conversion system, comparing its performance to a static bias approach.

FIG. 5 illustrates an example of a chip micrograph of an adaptive frequency conversion system.

FIG. 6 illustrates an example of conversion gain over RF frequency across LO powers.

FIG. 7A illustrates an example of port return loss S-parameters for a single-ended LO with differential IF, showing frequency response shifts.

FIG. 7B illustrates an example of RF port return loss with varying LO powers.

FIG. 8 illustrates an example of conversion gain and DC power consumption at 155 GHz RF and 140 GHz LO.

FIG. 9 illustrates an example of 1-dB input and output power compression at 155 GHz RF and 140 GHz LO, along with LO power detection voltage (VDET).

FIG. 10 illustrates an example of a frequency multiplier chain in a local oscillator system.

FIG. 11 illustrates an example of conversion gain performance across input power ranges, comparing bias-feedback adaptation with static biasing.

FIG. 12 illustrates an example of output power variation and DC current consumption for a static-biased and feedback-biased frequency doubler circuit.

FIG. 13 illustrates an example of a measurement setup for high-frequency band testing of an adaptive frequency conversion system with a chip micrograph.

FIG. 14 illustrates an example of a measurement setup for low-frequency band testing of an adaptive frequency conversion system, showing calibration and signal processing details.

FIG. 15 illustrates an example of measured conversion gain across a range of input powers, demonstrating the agreement between measured and simulated results.

FIG. 16 illustrates an example of conversion gain flatness across varying input power levels, confirming the benefits of bias feedback adaptation.

FIG. 17 illustrates an example of the saturated output power relationship, showing how the system maintains stable performance despite input power variations.

FIG. 18 illustrates an example of DC power consumption across varying output power levels, demonstrating the impact of bias feedback control on energy efficiency.

### DETAILED DESCRIPTION

Wireless systems for sensing and communication networks are under increasing demand to provide the fusion of the radar and radio into a single hardware platform to cooperatively take advantage of the wide spectrum availability in the frequency bands from mm-wave up to THz. The cooperation enhances communication by spatial localization and improves radar by distributed coordination in dynamic channel environments with a MIMO system. However, the power consumption of transmit and receive arrays increases at higher frequency and becomes prohibitive in applications such as handsets where the power budget is limiting.

In many high-frequency communication and sensing systems, local oscillator signals are used to translate signals from one frequency band to another. These signals can be generated through frequency converters (e.g., multipliers, mixers, dividers, and PLLs), which increase an input frequency to a higher output frequency. However, traditional frequency multipliers are often designed with fixed bias settings that do not adapt to changing signal conditions, potentially causing unnecessary power consumption. This can be of particular concern in applications that operate at millimeter-wave frequencies, where energy use can be significantly higher than at lower frequencies.

A common issue in these systems is that non-linearities in conventional frequency multipliers can lead to inconsistent control over the output power and conversion gain. When a device is biased for maximum performance at all times, it may draw the same amount of power even when full performance is not needed. This can be problematic in environments that prioritize energy efficiency, such as mobile platforms or other applications with limited power budgets.

Some existing designs attempt to address this challenge by optimizing transistor bias points for typical operating conditions. While these approaches may improve efficiency in certain scenarios, they do not always account for wide variations in input power or rapidly changing channel environments. As a result, systems can still experience either overspending of power resources or compromised performance when the operating conditions deviate from the assumed norm.

In some cases, these inefficiencies can degrade the overall effectiveness of phased array systems, which typically involve multiple frequency conversion stages. For example, a mobile communication device or portable radar may need to operate for extended periods on battery power while still providing high-resolution performance in dynamic channel conditions. Rigid, non-adaptive frequency multipliers in these applications may cause the system to consume more power than desired, potentially shortening operational life or reducing system responsiveness.

Some embodiments of the present disclosure relate to circuit techniques that can reduce power consumption in the LO chain to improve energy efficiency in the array receiver, particularly for adapting to dynamic channel environments where the received power (PRX) can vary by target or transmitter distance. To accommodate a high dynamic range of the received radar signal, the conversion gain of the mixer can be adjusted by saving LO power and, in some cases, reducing or eliminating additional variable-gain amplifiers in the signal path, thereby decreasing system power consumption and circuit area.

Some inventive concepts described herein relate to a subharmonic downconverter realized in a 90-nm SiGe BiCMOS process for D-band (110-170 GHz). Bias-feedback circuitry can adapt the LO current to enable gain control in the mixer through the LO power. The design can adjust the fourth harmonic content in a push-pull frequency multiplier to achieve a high multiplication factor without, in some cases, sacrificing additional area or power for a cascaded multiplier chain. Additionally, the design can inherently contain an LO power detector to monitor and, in some cases, support closed-loop gain control in a system.

Some inventive concepts described herein address the above or other issues by incorporating a bias-feedback approach in the frequency multiplier. This approach can dynamically adjust transistor bias levels in response to variations in output power or input signal conditions, thereby promoting more efficient power usage. By allowing the multiplier's gain and power consumption to adapt in real time, the system can facilitate a consistent and predictable output across a range of operating scenarios.

Some inventive concepts described herein relate to a frequency multiplier circuit that includes a push-pull transistor arrangement in conjunction with a bias-feedback network. The bias-feedback network can sense output power and tune the multiplier's operating point, reducing power consumption while preserving signal performance. Such adaptability may be advantageous for high-frequency communication or radar systems that operate at millimeter-wave frequencies and experience varying signal conditions.

Some inventive concepts described herein relate to an improvement over fixed-bias multiplier designs by offering an efficient and scalable solution for generating LO signals. By substituting conventional static bias approaches with a bias-feedback configuration, LOs in phased array systems can manage power usage more effectively, extending device operating duration in mobile platforms or increasing system capacity in larger-scale applications.

Frequency multiplication for LO generation can be utilized in various high-frequency applications, such as millimeter-wave phased array systems employed in radar, communications, or imaging. Conventional frequency multiplier circuits can often exhibit non-linear characteristics, making it challenging to maintain consistent control over output power and frequency conversion gain. This non-linearity can result in constant power consumption, irrespective of varying performance requirements, leading to inefficiencies, particularly in power-constrained environments such as mobile systems. These challenges underscore the need for more efficient frequency multiplier circuits that can adapt to different performance and power requirements.

Traditional frequency multiplier circuits often include transistors configured in a push-pull topology. The bases of these transistors can be biased with a static voltage, and the balanced input signal can be rectified to generate the desired harmonic of the input frequency. However, the non-linear relationship between the input and output power can complicate the control of frequency conversion gain and overall power consumption. This non-linearity can be further exacerbated by variations in the input power, making it difficult to maintain consistent output power and efficiency.

Some inventive concepts described herein relate to an adaptive frequency multiplier circuit with bias-feedback linearization, which may address some inefficiencies of conventional frequency multipliers. The adaptive frequency multiplier circuit can dynamically adjust the bias voltage at the transistor bases in response to changes in output power, thereby linearizing the gain and reducing conversion gain variation over a wide range of input powers. By enabling more reliable control over frequency conversion gain and power consumption, the inventive concepts can improve the performance and efficiency of millimeter-wave phased array systems.

Some inventive concepts described herein relate to the integration of a bias-feedback network within the adaptive frequency multiplier. The bias-feedback network can include a feedback resistor and an additional transistor, which can dynamically adjust the bias voltage at the bases of the main transistors based on detected changes in output power. Such an approach can mitigate the non-linearity observed in conventional frequency multipliers and provide a high degree of control and predictability in the output power, enabling reconfigurability in system performance and power consumption.

Some inventive concepts described herein relate to the application of the adaptive frequency multiplier in transmit and receive systems requiring LO generation. By allowing for the adjustment of LO power, these concepts can facilitate a trade-off between direct current (DC) power consumption and the linearity, noise, and gain of frequency translation circuitry. This reconfigurability can be useful in various applications, such as in mobile systems and other power-constrained environments, where optimizing power usage based on the channel environment and system integration needs is advantageous.

Some inventive concepts described herein relate to mechanisms for enhancing the scalability of phased array systems. For instance, in larger scaled systems where providing maximum LO power or DC power may be limited, the adaptive frequency multiplier can enable reliable implementation by trading off performance for reduced power consumption. This capability can be beneficial in various operational settings, including mobile systems and complex phased array configurations.

Some inventive concepts described herein relate to an adaptive frequency multiplier for local oscillator generation at an integer value of the input frequency, ranging from 2× to 4×, with a feedback linearized gain. The adaptive frequency multiplier can be useful for higher-frequency millimeter-wave phased array systems operating above 100 GHz, as it can reduce overall power consumption in the receiver array and enable digital beamforming techniques that adjust the conversion gain per channel.

Some inventive concepts described herein can represent an advancement in the field of frequency multiplier circuits for high-frequency applications. By incorporating a bias-feedback linearization network, these inventive concepts can refine the approach to controlling frequency conversion gain and power consumption. The disclosed techniques can enable more efficient and adaptable phased array systems, conserving power and providing reliable performance in diverse operational environments.

### Example Adaptive Frequency Conversion System

A frequency conversion system changes the frequency of an input signal to a different frequency. Frequency conversion systems are commonly used in communication and radar systems. Conventionally, frequency conversion systems may have trouble keeping the output stable and efficient when input conditions change due to varying signal strengths and frequencies. Frequency conversion systems can also exhibit non-linear characteristics, leading to unpredictable performance.

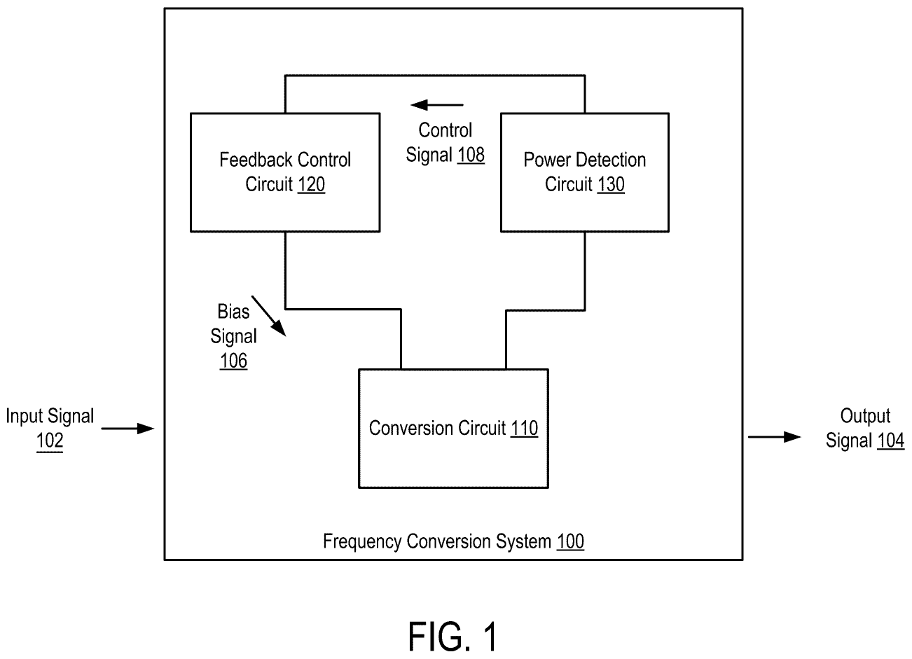

FIG. 1 illustrates an example adaptive frequency conversion system 100. The adaptive frequency conversion system 100 uses a bias signal 106 to control the gain of the conversion circuit 110, thereby substantially linearizing the gain and mitigating the non-linearity observed in conventional frequency multipliers. The adaptive frequency conversion system 100 is configured to automatically adjust the bias signal 106 based on characteristics of at least one of the input signal 102 or the output signal 104, such as power levels or frequency. The adaptive frequency conversion system 100 detects characteristics and/or changes thereto in the input signal 102 or the output signal 104 and modifies the bias signal 106 to facilitate a stable and efficient output signal 104. By dynamically adjusting the gain through the bias signal 106, the adaptive frequency conversion system 100 facilitates a consistent and reliable output signal 104, even when input conditions vary. The adaptive frequency conversion system 100 can provide a high degree of control and predictability in the output power, allowing the adaptive frequency conversion system 100 to operate efficiently, improving power use and performance in real-time.

The adaptive frequency conversion system includes a conversion circuit 110, a power detection circuit 130, and a feedback control circuit 120. The conversion circuit 110 obtains the input signal 102 and a bias signal 106 and generates an output signal 104 at a converted frequency. The implementation of the conversion circuit 110 can vary across embodiments. For example, the conversion circuit 110 can include, but is not limited to, a multiplier circuit, a mixing circuit, a subharmonic mixer, or a frequency downconverter. In some cases, the conversion circuit 110 can include any circuit configured to modify the frequency of an input signal 102.

The power detection circuit 130 is electrically coupled with the conversion circuit 110 and/or the feedback control circuit 120. The power detection circuit 130 is configured to monitor one or more characteristics of the input signal or the output signal. The one or more characteristics can include, but are not limited to, a power level, frequency, amplitude, phase, signal strength, or signal-to-noise ratio (SNR). In some cases, the power detection circuit 130 can generate a control signal 108 based on the one or more characteristics to facilitate dynamic adjustment by the feedback control circuit 120.

In some embodiments, the power detection circuit 130 can be implemented using transistors and associated components, such as resistors and capacitors, to filter and stabilize the detected signal. For example, the power detection circuit 130 can monitor an output current and utilize resistors and capacitors to achieve detection and filtering. It will be appreciated that the power detection circuit 130 can be implemented using various technologies and methodologies. For example, the power detection circuit 130 can include, but is not limited to, a rectifier circuit to detect the power level, a frequency discriminator to monitor frequency changes, or a phase detector to measure phase variations. As another example, the power detection circuit 130 can incorporate an amplitude detector to assess signal strength or an SNR meter to evaluate signal quality. In some such cases, these configurations can facilitate precise monitoring and detection of one or more the characteristics.

The feedback control circuit 120 can generate or adjust the bias signal 106 provided to the conversion circuit 110. This adjustment can be performed to dynamically regulate the output signal 104 of the frequency conversion system 100. In some cases, the bias signal 106 causes the conversion circuit 110 to decrease the gain of the conversion circuit 110 when the output power increases and causes the conversion circuit 110 to increase the gain of the conversion circuit 110 when the output power decreases. In some cases, the feedback control circuit 120 adjusts the bias signal 106 based on the control signal received from the power detection circuit 130.

The feedback control circuit 120 can include components such as, but not limited to, resistors, capacitors, or transistors configured to provide bias feedback to the conversion circuit 110. In some cases, the bias signal 106 is a bias current, and the feedback control circuit 120 can dynamically adjust the bias current by monitoring the output power and making adjustments to the bias signal 106. In some cases, the feedback control circuit 120 can be part of the conversion circuit 110.

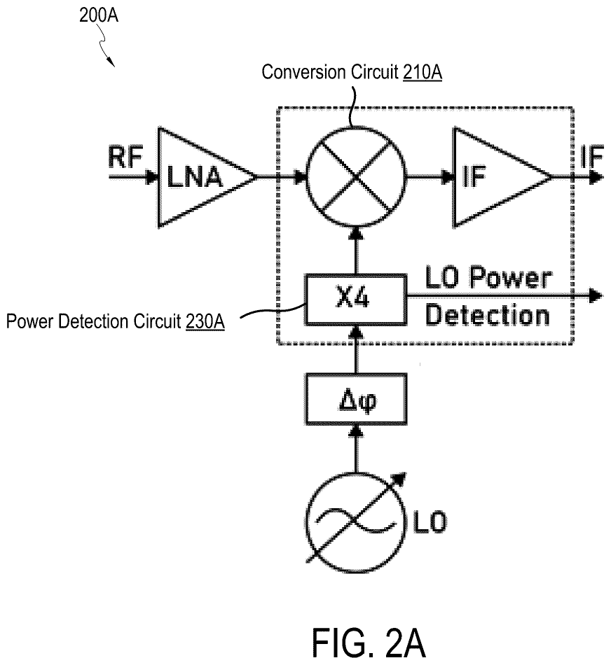

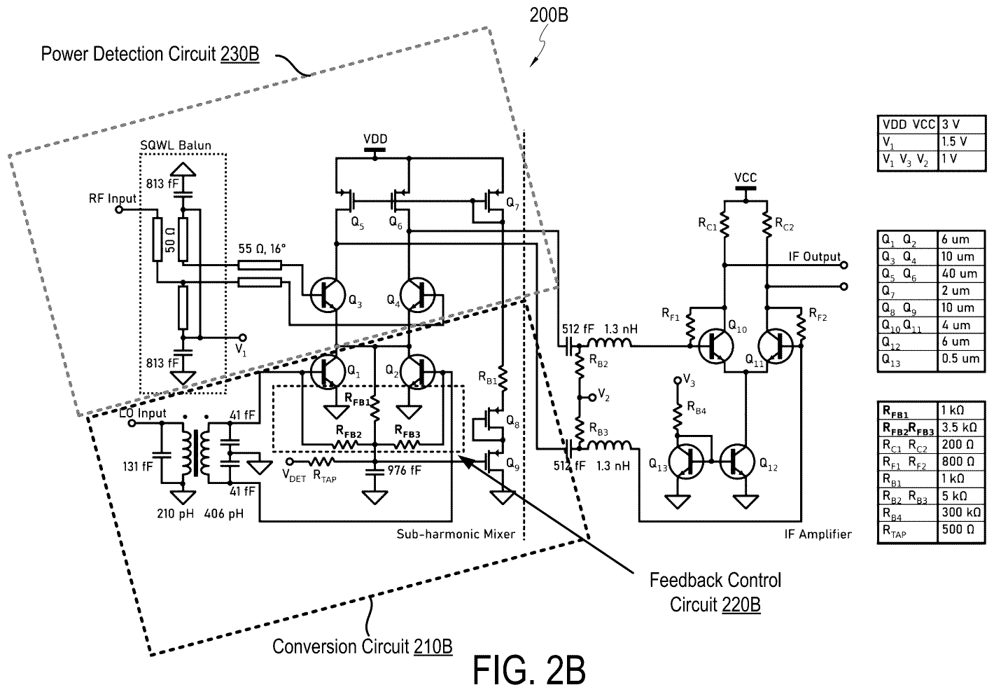

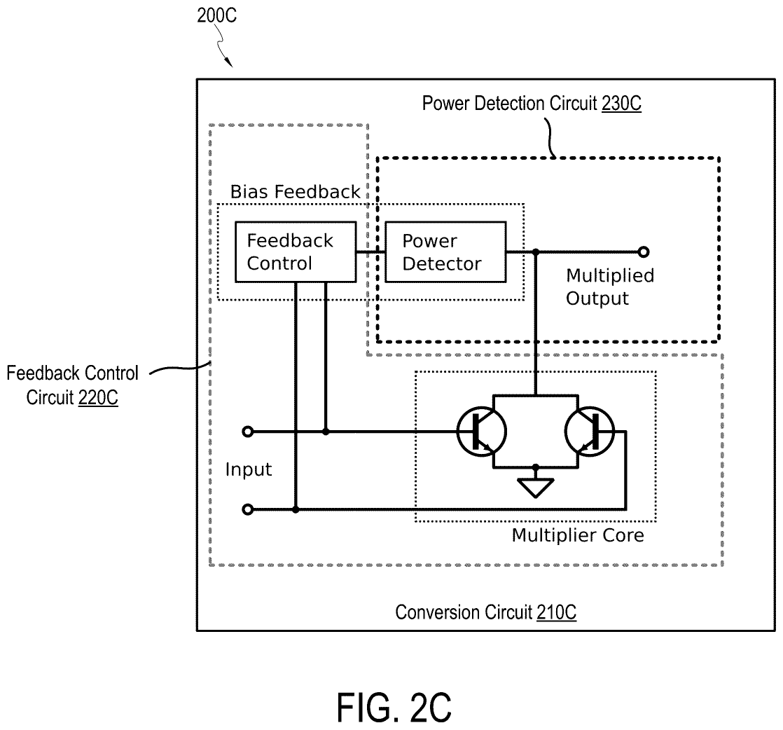

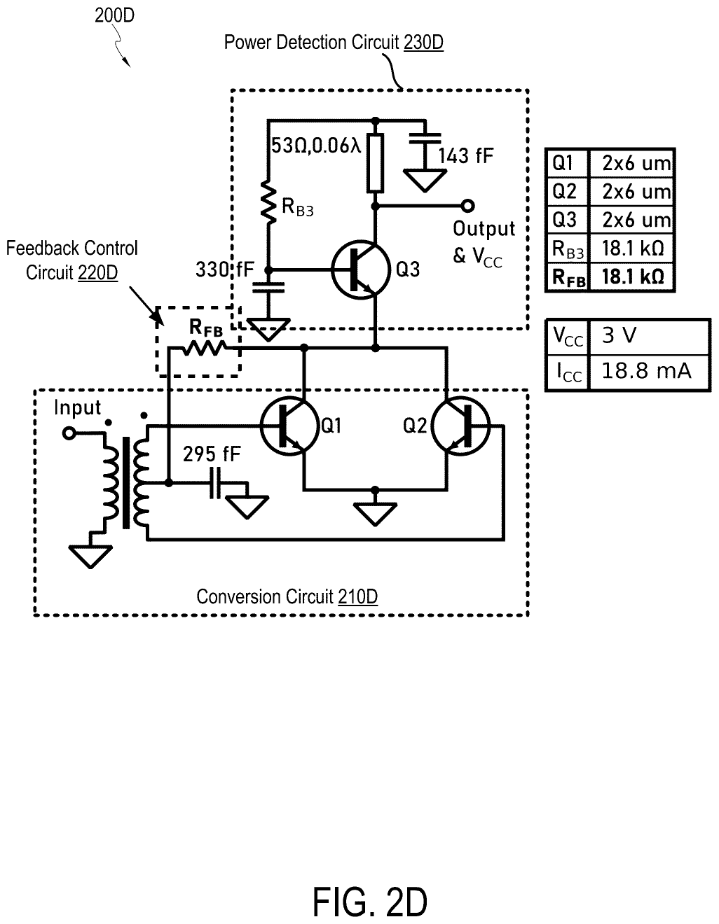

FIG. 2A illustrates an example adaptive frequency conversion system 200A, which may be an embodiment of an adaptive frequency conversion system designed for local oscillator (LO) signal processing with power adaptation. The system 200A can include a low noise amplifier (LNA), a conversion circuit 210A (e.g., a mixer), a power detection circuit 230A, and an intermediate frequency (IF) amplifier.

The LNA can be configured to receive and amplify an incoming RF signal, which may enhance the signal strength and reduce noise before frequency conversion. The amplified RF signal can then be provided to the conversion circuit 210A for further processing.

In some embodiments, the conversion circuit 210A may include a mixer that can combine the amplified RF signal with a local oscillator (LO) signal to generate an intermediate frequency (IF) output. The LO signal may undergo a phase shift (Δφ) before being processed by the power detection circuit 230A.

The power detection circuit 230A may include a frequency multiplier (×4) configured to increase the frequency of the LO signal by a factor of four. Additionally, the power detection circuit 230A can be configured to monitor and regulate LO power levels. This configuration may allow for adaptive biasing and dynamic gain control in the system, thereby enabling improved power efficiency and performance in varying operating conditions.

FIG. 2B illustrates another example adaptive frequency conversion system 200B. The system can include a conversion circuit 210B, a feedback control circuit 220B, and a power detection circuit 230B. The frequency conversion system 200B can be an embodiment of the frequency conversion system 100 of FIG. 1.

The conversion circuit 210B can be configured to receive an input signal and generate an output signal at a converted frequency. This circuit can include a subharmonic mixer, utilizing transistors Q1 and Q2 in a push-pull configuration to generate the fourth harmonic of the input signal. The RF input is split through a sub-quarter-wavelength (SQWL) balun into the single-balanced mixer. The tail current source of the mixer can be replaced with a push-pull frequency multiplier, forming a cascode structure with the active mixer. This configuration can increase the conversion gain by suppressing the Miller effect and save power by reusing the current for the multiplier in the mixer. The load of the mixer can include a pair of saturated PFETs biased through a common mode connection to the frequency multiplier. In some cases, the conversion circuit 210B includes a subharmonic-based downconverter.

The LO path can include a transformer balun that produces a differential LO to drive a pair of HBTs (Q1, Q2) that generate the fourth harmonic. The fourth harmonic LO signal is applied in common mode to Q3 and Q4 to facilitate frequency conversion. Since the LO is presented in the common mode in the mixer, it can be suppressed by using differential mode in the RF path through Q3 and Q4, and the IF path through Q10 and Q11. The IF path can also include a differential wideband transimpedance amplifier (TIA) with inductive peaking to buffer and amplify the converted signal from the mixer into differential voltage outputs.

The power detection circuit 230B can be electrically coupled to the conversion circuit 210B and/or the feedback control circuit 220B. The power detection circuit 230B can be configured to monitor characteristics of the output signal, such as power levels. The power detection circuit 230B can include transistors (e.g., Q3, Q4, Q5) and associated components like resistors (R_{B1},R_{B2},R_{B3}) and capacitors (e.g., 512 fF, 1.3 nH) to filter and stabilize the detected signal. The power detection circuit 230B can generate a control signal based on these characteristics. This control signal can be used by the feedback control circuit 220B to adjust the bias signal, thereby improving the performance of the conversion circuit 210B.

The feedback control circuit 220B can be electrically coupled to, or a part of, the conversion circuit 210B and can be configured to adjust the bias signal provided to the conversion circuit 210B. The feedback control circuit 220B can include components such as resistors R_{FB1}, R_{FB2}, R_{FB3}, and/or capacitors to dynamically regulate the output power of the conversion circuit 210B. The feedback mechanism can adjust the bias current to maintain stable operation by decreasing the gain of the conversion circuit 210B when the output power increases and increasing the gain when the output power decreases. The feedback control circuit 220B can provide bias feedback to the multiplying transistors to support frequency generation over a wide range of LO powers.

FIG. 2C illustrates an example adaptive frequency multiplication system 200C. The system 200C can include a conversion circuit 210C, a feedback control circuit 220C, and a power detection circuit 230C. The frequency conversion system 200C can be an embodiment of the frequency conversion system 100 of FIG. 1.

In some embodiments, the conversion circuit 210C may include a multiplier core having transistors configured to receive an input signal and generate a multiplied output signal. The input signal may be processed through the multiplier core to facilitate frequency multiplication.

The power detection circuit 230C can be configured to monitor the multiplied output signal to detect characteristics such as power levels. Based on the detected characteristics, the power detection circuit 230C may generate a control signal that can be used to adjust the operation of the system.

The feedback control circuit 220C may be configured to generate and apply bias feedback to the multiplier core. The bias feedback may be dynamically adjusted based on the control signal received from the power detection circuit 230C, thereby regulating the operating conditions of the frequency multiplier.

In some embodiments, the bias feedback mechanism may include a feedback control module and a power detector, which can cooperate to regulate the bias conditions of the multiplier core. By adapting the bias in response to variations in the multiplied output, the system 200C may enhance power efficiency and maintain a stable conversion gain.

The adaptive frequency multiplication system 200C may advantageously facilitate consistent and reliable frequency multiplication by dynamically adjusting bias conditions based on real-time output characteristics. This configuration can improve overall system efficiency and stability across varying signal conditions.

FIG. 2D illustrates an example adaptive frequency conversion system 200D. The system 200D can include a conversion circuit 210D, a feedback control circuit 220D, and a power detection circuit 230D. The frequency conversion system 200D can be an embodiment of the frequency conversion system 100 of FIG. 1.

The conversion circuit 210D can be configured to receive an input signal and generate an output signal at a converted frequency. The conversion circuit 210D can include transistors Q1 and Q2, which can form a push-pull frequency doubler. The input signal can be processed through passive components such as capacitors (e.g., 295 fF) and inductors to facilitate the frequency conversion. In some cases, the push-pull configuration can enhance the efficiency of the frequency conversion process by effectively doubling the input frequency.

The power detection circuit 230D can be electrically coupled to both the conversion circuit 210D and the feedback control circuit 220D. It can be configured to monitor characteristics of the output signal, such as power levels. The power detection circuit 230D can include a transistor (Q3) and associated components like resistors R_{B3} and capacitors (e.g., 143 fF, 330 fF) to filter and stabilize the detected signal. The power detection circuit 230D can generate a control signal based on these characteristics. This control signal can be used by the feedback control circuit 220D to adjust the bias signal, thereby improving the performance of the conversion circuit 210D.

The feedback control circuit 220D can be electrically coupled to the conversion circuit 210D and the power detection circuit 230D and can be configured to generate or adjust a bias signal provided to the conversion circuit 210D. The feedback control circuit 220D can include components such as a feedback resistor R_{FB}. In some cases, the feedback control circuit 220D can dynamically regulate the output power of the conversion circuit 210D by adjusting the bias current. For example, the feedback control circuit 220D can decrease the gain of the conversion circuit 210D when the output power increases and can increase the gain of the conversion circuit 210D when the output power decreases, thereby maintaining stable operation.

As shown, in some cases, the adaptive frequency conversion system 200D can be implemented as a frequency doubler with bias-feedback adaptation. In some cases, heterojunction bipolar transistors (HBTs) Q1 and Q2 form an active push-pull doubler, while Q3 acts as a common-base amplifier to buffer the current and maintain bias conditions. The current flowing through Q3 is reused by the push-pull doubler, thereby saving power compared to an AC-coupled connection to a power amplifier stage. The feedback control circuit 220D includes a bias-feedback resistor (RFB) that adapts the conversion gain over a wide range of input powers, ensuring stable performance and efficiency across varying input levels.

### Dynamic Subharmonic Generation

A typical push-pull frequency multiplier or sub-harmonic mixer uses a second harmonic. In some cases, an adaptive frequency conversion system, as disclosed herein, includes a subharmonic mixer that utilizes the fourth harmonic from a push-pull frequency multiplier implemented with transistors Q1 and Q2, shown in FIG. 2B. The harmonic content of the combined collector currents I_{C} of Q1 and Q2 can depend on the conduction cycle, which can be controlled through their base voltage bias.

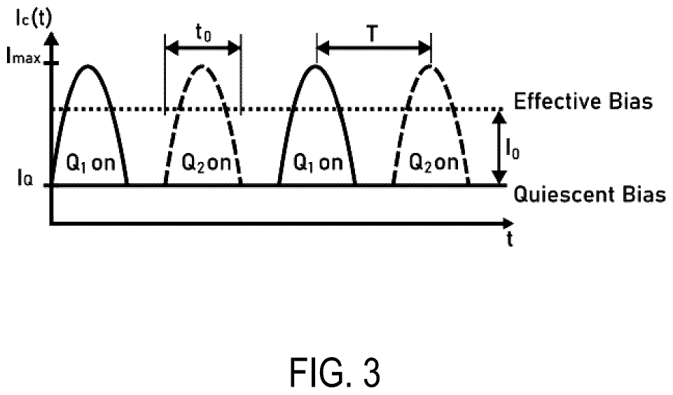

Modeling the collector current as a half-wave rectified sinusoidal pulse train, illustrated in FIG. 3, the Fourier series expansion presents the current harmonics as in Equation 1.

$${I}_{n} = {I}_{max} \frac{4 {t}_{0}}{π T} \{ \begin{matrix}1 & , if n = 0 \\ 2 \cdot \vert \frac{cos ( \frac{n π {t}_{0}}{T} )}{1 - {( \frac{n π {t}_{0}}{T} )}^{2}} \vert & , if n even \\ 0 & , if n odd\end{matrix} \qquad ( Equation 1 )$$

A maximum fourth harmonic current of 0.27·Iₘₐₓ can be obtained with conduction cycle t₀/T=0.17. The ratio between the maximum harmonic current and generated DC current is I₄/I₀=1.25 for the maximum fourth harmonic. Despite the lower current in the fourth harmonic compared to the second, the ratio between the desired harmonic and generated DC current is fixed relative to the second or fourth harmonic. Thus, configuring a push-pull frequency multiplier for the fourth harmonic generation does not sacrifice DC power consumption.

In a typical multiplier, the bases of Q1 and Q2 are biased with a static voltage which is tuned for a particular LO input power. This method, however, may not provide the best bias across input powers. As shown by the DC current where n=0 in Equation 1, the average effective output current of Q1 and Q2 is I_{C}=I_{Q}+I0, where I_{Q} is the quiescent bias current and I₀ is the additional current generated from the rectification of the input sinusoid. The additional current causes the transconductance to change with output power, a source of nonlinear gain in the multiplier.

To counteract the current variation, large feedback resistances, R_{FB1}, R_{FB2}, and R_{FB3}, from the collectors of Q1 and Q2 set the base bias and to compensate for the additional current created by the output waveform at DC. If it is considered that consider V_{BE1,2}≈V_{BE3,4}, and I_{C3,4}≈I_{C1,2},

$${I}_{C 3 , 4} = {β}_{1 , 2} \frac{{V}_{1} - 2 {V}_{BE}}{{R}_{RB 1} + {R}_{FB 2} ‖ {R}_{FB 3}} \qquad ( Equation 2 )$$

Thus, the feedback resistance can reduce the influence from the additional rectified DC current. Although feedback compensates for the additional rectified current, the current change may not be completely cancelled due to variations in the effective time-averaged β_{1,2} over power variation. The feedback bias allows for a gradual change in gain over a wider range of LO input powers compared to the static bias approach.

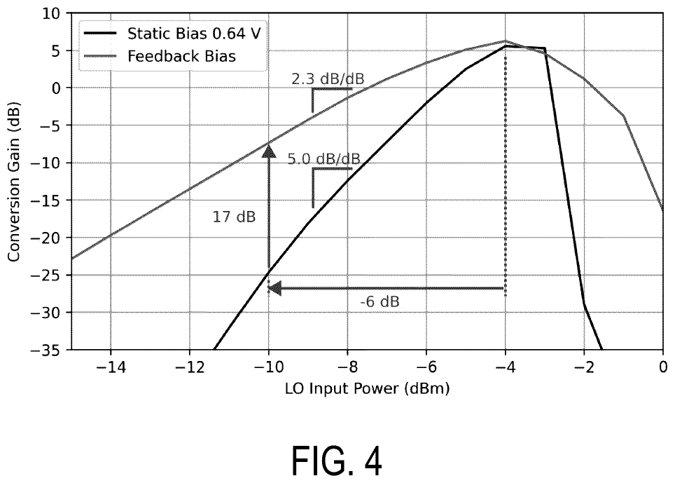

FIG. 4 illustrates an example of the effect of bias feedback in the adaptive frequency conversion system 200B of FIG. 2B (e.g., a downconverter), compared to a typical static bias approach. The conversion gain remains higher over reduced LO power and improves the robustness of the circuit to LO power variation. With a −6 dB LO power backoff from peak conversion gain, the feedback biased circuit has 17 dB more gain than the static biased version. Additionally, the feedback network provides voltage VDET corresponding to output current, enabling monitoring of conversion gain. In this configuration, the power detection circuit 230B functions as both a power detection circuit and a mixer that performs frequency downconversion for the RF signal, while the conversion circuit 210B operates as a conversion circuit that generates the fourth harmonic as the LO signal. Together, the conversion circuit 210B and the power detection circuit 230B form the frequency downconversion system 200B, where the feedback control circuit 220B generates a bias signal for the conversion circuit 210B based on a control signal received from 230B.

### Example Measurement Results

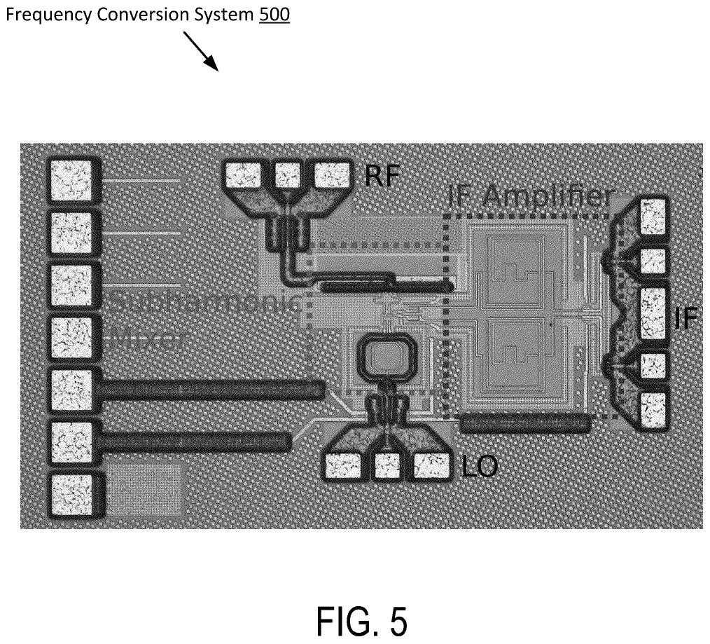

FIG. 5 illustrates an example adaptive frequency conversion system 500 with dimensions of 1.18 mm×0.68 mm and core area of 0.56 mm×0.35 mm. Measurements were made on the adaptive frequency conversion system 500 using a 3-V supply on VDD and VCC, with quiescent currents of 8.6 mA to the IF amplifier and 0.9 mA to the mixer. A VDI PM5B power meter was used as the power reference for calibrating the D-band extender as the RF input source, and output leveling was performed with an electronically controlled variable attenuator. DC blocks were used with an oscilloscope to measure the differential IF. The LO was directly provided by a signal generator.

The gain of the adaptive frequency conversion system 500 was measured across a range of LO powers across frequency with results in agreement with the simulation.

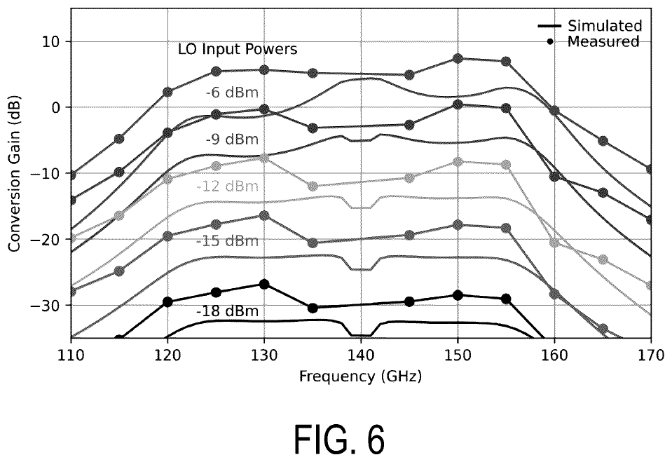

FIG. 6 illustrates an example of the conversion gain over RF frequency across LO powers on a 140 GHz LO, with −24 dBm of RF input power. The supplied RF input power was −24 dBm and the LO was supplied at 35 GHz for an effective 140 GHz LO at the mixer. With −6 dBm of LO power, the maximum gain across the band was 7.4 dB at 150 GHz with a 3-dB bandwidth of 35 GHz, spanning 123 GHz to 158 GHz.

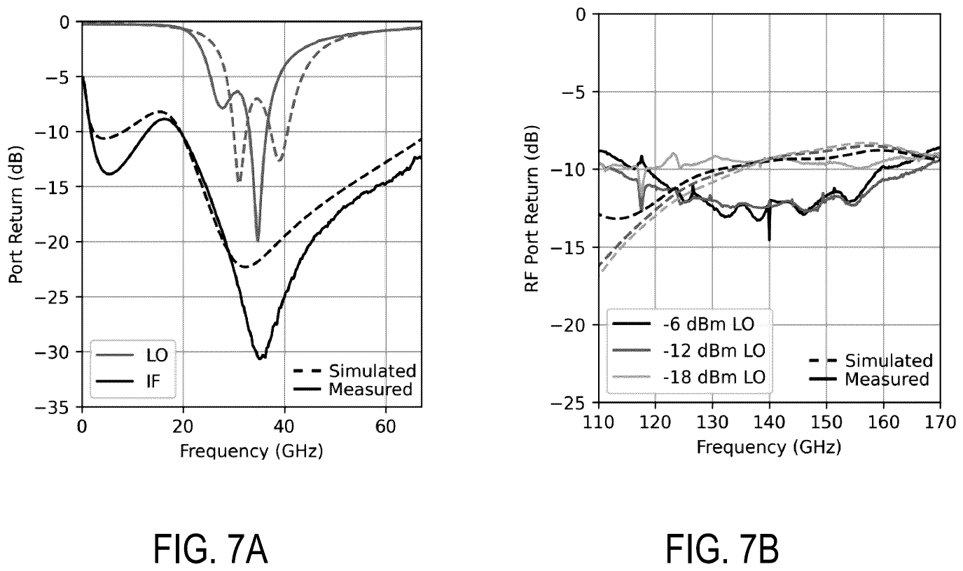

FIG. 7A illustrates an example of the port return S-parameters for a single-ended LO with differential IF. The measured gain of the adaptive frequency conversion system 500 is higher than simulated due to a frequency shift in the return loss of the LO, shown in FIG. 7A. The shift leads to a better match at the LO frequency and more delivered LO power.

FIG. 7B illustrates an example of the port return S-parameters for the RF port with varying LO powers. The RF return loss, shown in FIG. 7B, which was close to simulation with slightly better return loss.

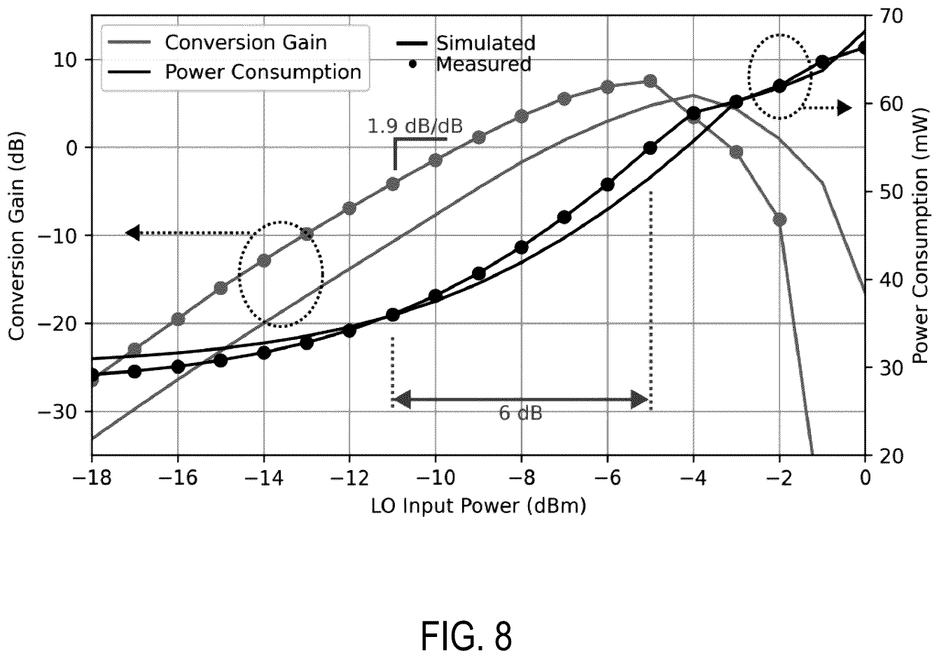

FIG. 8 illustrates an example of the conversion gain and DC power consumption at 155 GHz RF and 140 GHz LO, with −24 dBm of RF input power. Measurements at 155 GHz with a 140 GHz LO confirming the relationship between LO power and resulting conversion gain are shown in FIG. 8. The gain of the adaptive frequency conversion system 500 was controlled with LO power at 1.9 dB/dB, leading to the ability to reliably trade off between conversion gain and power consumption. A maximum gain of 7.5 dB was observed at 155 GHz with −5 dBm of input power, while consuming 55 mW of DC power. By backing off LO power from −5 dBm to −11 dBm to decrease gain from the peak by 11.7 dB, DC power consumption was decreased by 19 mW, 35% less than consumption at peak gain.

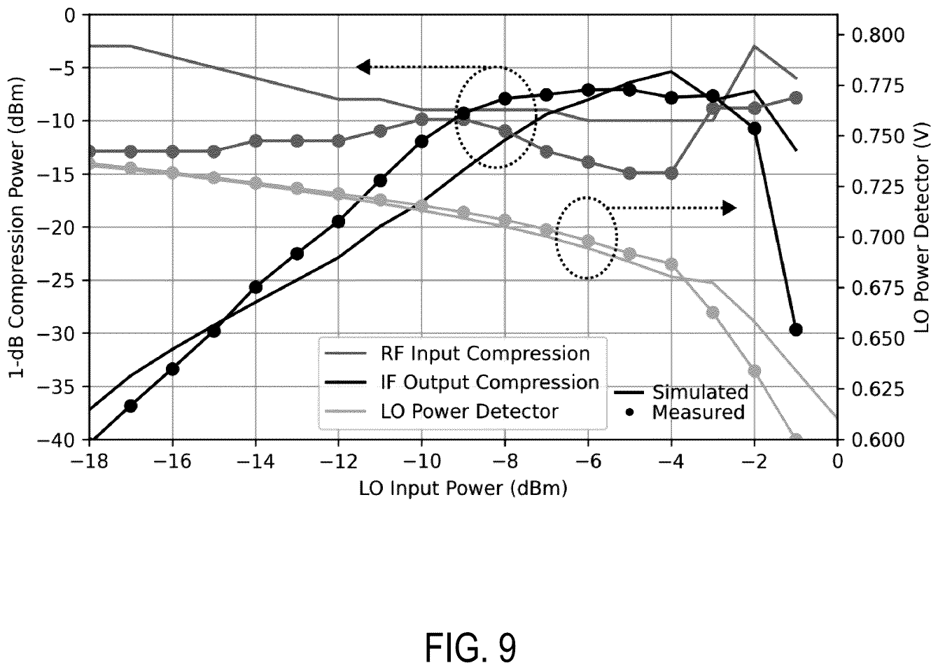

FIG. 9 illustrates an example of the 1-dB input and output power compression at 155 GHz RF and 140 GHz LO with LO power detection voltage (VDET). The LO power detection voltage VDET was measured to be close to simulation, shown in FIG. 9. The power detection is predictable and monotonic, making it suitable for use in system level control of LO power. With a 155 GHz RF and 140 GHz LO, the lowest demonstrated 1-dB input compression is −15 dBm, shown in FIG. 9. With less than −4 dBm of LO power, the input compression remains fixed between −15 dBm and −10 dBm while the output compression changes with LO power.

An adaptive frequency conversion system, according to some embodiments of the inventive concept, can be presented with bias feedback to enable adaptation of performance and power consumption through LO power. The system can exploit the fourth harmonic content of a push-pull frequency multiplier to achieve a high multiplication factor without additional area, power consumption, or LO power requirements typical of cascaded multiplier chains, exemplified in Table 1. This design adaptation can make the system suitable for applications in joint radar and radio systems operating in dynamic environments.

TABLE 1

| | This | | | |
|---|---|---|---|---|
| Reference | Work | [3] | [6] | [7] |
| Technology | 90-mm | 90-nm | 130-nm | 130-nm |
| | SiGe | SiGe | SiGe | SiGe |
| Subharmonic | 4 | 2 | 2 | 1 |
| f_{C} (GHz) | 140 | 136 | 121 | 140 |
| BW_{3 dB} (GHz) | 35 | 38 | >14 | 35 |
| Gain (dB) | 7.5 | 5.1 | 4 | 32 |
| P_{i1 bB} (dBm) | −15 | −7 | — | −41 |
| LO (dBm) | −5 | 2 | 7 | −2 |
| P_{DC} (mW) | 55 | 51 | 89 | 65 |
| Area (mm²) | 0.196 ^{†} | 0.450 ^{†} | — | 0.191 ^{†} |

^{†} Area without pads.

### Frequency Doubler

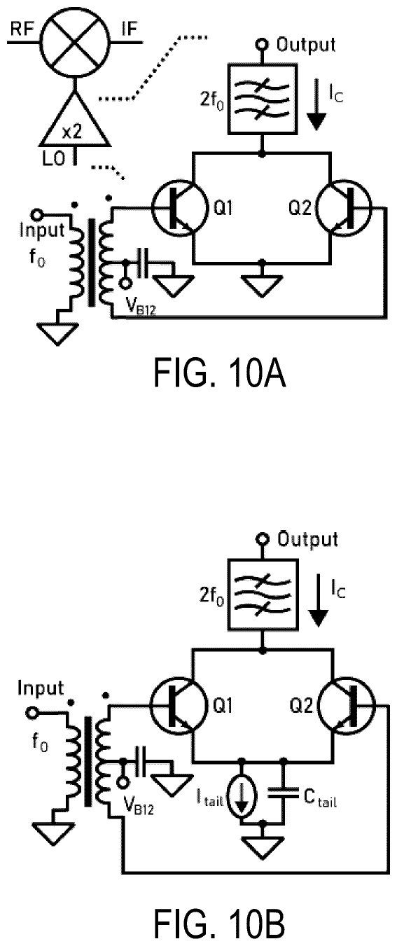

Wireless backhaul networks are under increasing demand to provide fiber-like data rates, spurring interest for the wide spectrum availability in the 100-300 GHz frequency band. However, the power consumption of transmit and receive arrays increases at higher frequency and the reduced area occupied by a single element creates a prohibitive thermal flux in small antenna apertures. The LO chain, illustrated in FIG. 10, multiplies a reference frequency and amplifies the LO signal for frequency conversion. Based on the frequency multiplication factor and the LO power required to drive the mixer into saturation, the LO chain above 100 GHz places significant demands on the circuit power consumption. Circuit techniques that reduce power consumption in the LO chain support more energy efficiency in the transmitter and receiver.

As wireless link requirements change, the conversion gain of the mixer can be adjusted with LO power, eliminating other variable-gain amplifiers in beamforming applications, further decreasing system power consumption and area. A variable power frequency multiplier can adaptively respond to link and power requirements.

The basic frequency multiplier is illustrated in FIG. 10A and uses push-pull transistors operating in class B or C mode. To increase the conversion of the input frequency f₀ to 2 f₀, the doubler might include a bypassed resistive degeneration or use a bypassed tail current as shown in FIG. 10B. These methods consume voltage headroom, which require either higher voltage operation or sacrificing maximum output power in a low voltage system. Referring back to FIG. 3, it illustrates an instantaneous output current from a frequency doubler and its time-average impact on bias.

A G-band (170-260 GHz) frequency doubler is disclosed, realized in a 90-nm SiGe BiCMOS process. In some cases, the frequency doubler can be an embodiment of the conversion circuit 110 of FIG. 1. Bias-feedback circuitry adapts the conversion gain over a wide range of input powers. At 190 GHz, the doubler has a peak gain of −2.0 dB and remains within 3 dB of the peak gain over a 13 dB input power range. The doubler without pads has compact dimensions of 95 μm×135 μm, which makes it suitable for an LO chain in an array.

### Push-Pull Frequency Doublers

A schematic of an example doubler is presented in FIG. 2D. Heterojunction bipolar transistors (HBTs) Q1 and Q2 form an active push-pull doubler, while Q3 forms a common-base amplifier to buffer the current and to maintain bias conditions. The current flowing through Q3 is reused by the push-pull doubler, saving power compared to an AC-coupled connection to a power amplifier stage.

In a typical doubler, the bases of Q1 and Q2 are biased with a static voltage V_{B12}, shown in FIG. 10A. The frequency doubler creates an output waveform that contains the desired second harmonic of the sinusoidal input frequency by rectifying a balanced signal from the input balun. Using the Fourier series expansion of the output as a current cosine pulse train, it can be observed that the output waveform creates additional DC current in addition to the output harmonics of interest. The average effective output current is I_{C}=I_{Q}+I₀, where I_{Q} is the quiescent bias current and I₀ is the additional current generated from the rectification of the input sinusoid.

This additional current from the output waveform changes with input voltage vᵢ on the bases of Q₁ and Q₂. The AC output current can be estimated from the linearization of the small-signal collector current iₑ, based on the DC collector current Iₑ through the devices, e.g., i_{C}=Gₘ(I_{C})vᵢ, where Gₘ is the time-average effective transconductance. The bias shift is calculated from:

$${I}_{0} = \frac{4 {t}_{0}}{π T} {i}_{C} = \frac{4 {t}_{0}}{π T} {G}_{m} ( {I}_{Q} + {I}_{0} ) {v}_{i} . \qquad ( Equation 3 )$$

Since the transistor transconductance is sensitive to additional rectified current, i.e. Gₘ (I₁+I₀), the inherently non-linear transconductance causes the conversion gain for a static bias doubler to change with the input power. The result is that the frequency multiplier would have high gain only within a narrow range of input powers, and the sensitivity to input power diminishes the ability to control and deliver a desired output power in a system. Using a bypassed tail current source on Q₁ and Q₂, as shown in FIG. 10B, can force the DC current to be constant at the expense of power consumption.

### Adaptive Bias Feedback

A resistive feedback technique is disclosed herein, using frequency doublers to change base bias voltage (V_{B1} and V_{B2}), which mitigates the decrease in the bias current with decreasing input power to maintain gain. Transistor Q₃ not only provides amplification but also output current detection, while resistor R_{FB} implements the feedback for adaptation. In some cases, this technique does not have the drawback of increased power consumption from additional components for bias control.

The time average V_{BE3} decreases in response to a decrease in effective bias current Iₑ caused by the output waveform. The voltage signal from V_{BE3} is fed back through resistor R_{FB} into the bases of Q₁ and Q₂ to compensate for the change in DC bias current. The AC component is not significantly affected by the resistive feedback, because the feedback resistance is large compared to the emitter impedance of Q₃. In the following DC analysis of the biasing system, Q₁ and Q₂ are combined into an equivalent Q₁₂, because they are shorted together at DC. The Q3 base voltage,

$${V}_{B 3} = {V}_{CC} - \frac{{I}_{C 3}}{{β}_{3}} {R}_{B 3}$$

changes with the collector current. In this work, V_{B3} is set to 2.2V to maximize output voltage swing. If it is considered that V_{BE3}≈V_{BE12} and I_{c3}≈I_{c12}, then:

$${I}_{C 3} = {β}_{12} \frac{{V}_{B 3} - 2 {V}_{BE}}{{R}_{FB}} = \frac{{V}_{CC} - 2 {V}_{BE}}{{R}_{FB} / {β}_{12} + {R}_{B 3} / {β}_{3}} . \qquad ( Equation 4 )$$

In this manner, the bias current for the frequency doubler is set by V_{CC} and a selection of R_{FB} and R_{B3}, reducing the influence from the additional rectified DC current through V_{BE}. Instead of being dependent on a non-linear Gₘ (I_{Q}+I₀), the gain with resistive feedback is dependent on Gₘ (I_{c3}).

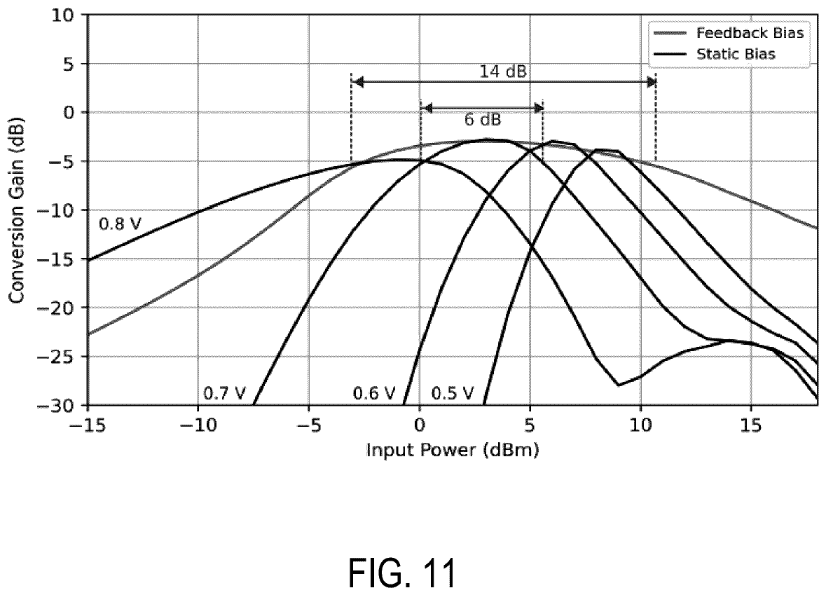

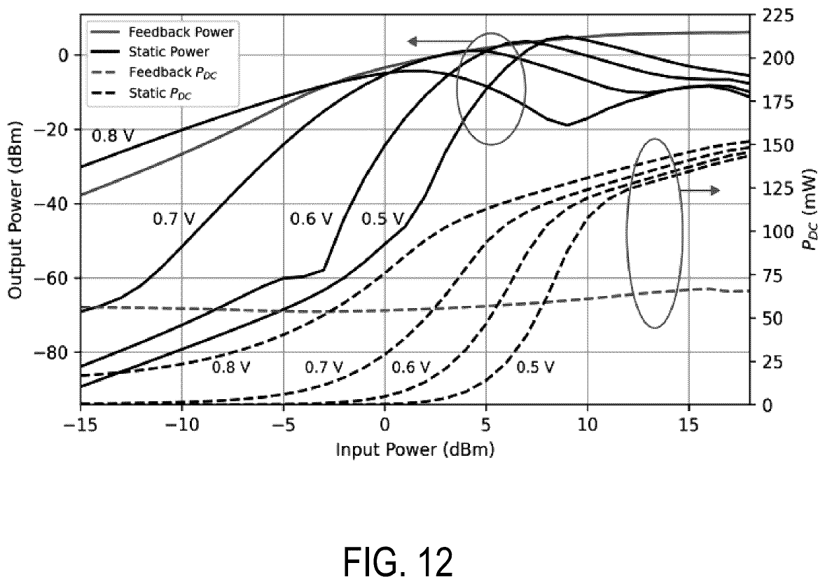

The effect of the input power on gain with this bias-feedback adaptation is illustrated in FIG. 11, where the conversion gain varies by less than 3 dB from the peak value over a 14-dB input power range, compared to only a 6-dB input power range in the static biasing case illustrated in the black curves. FIG. 12 plots the output power variation and DC current for the static and bias-feedback doubler circuit. While the static biasing produces similar peak output power as the feedback case, static biasing is strongly dependent on the input power with rapidly changing current consumption. The bias-feedback circuit maintains bias current across a large input power range and delivers the same saturated power as a static-bias circuit with a bias tuned for a particular input power to deliver maximum power.

### Measurements And Results

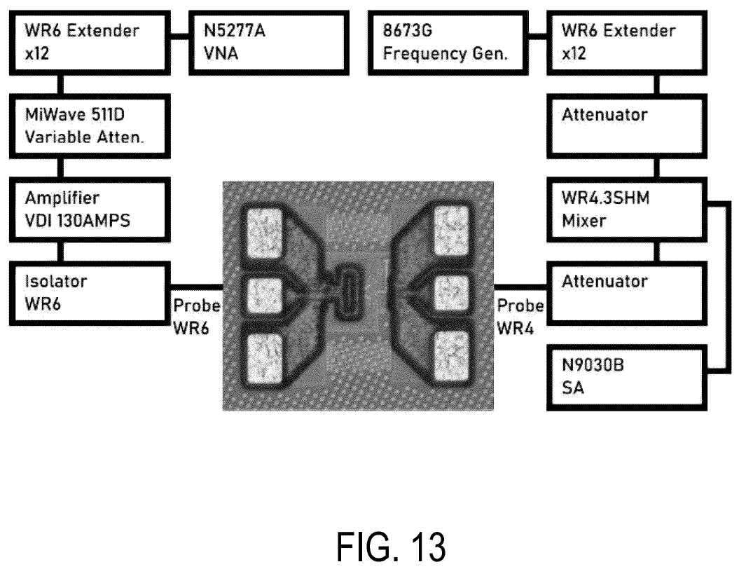

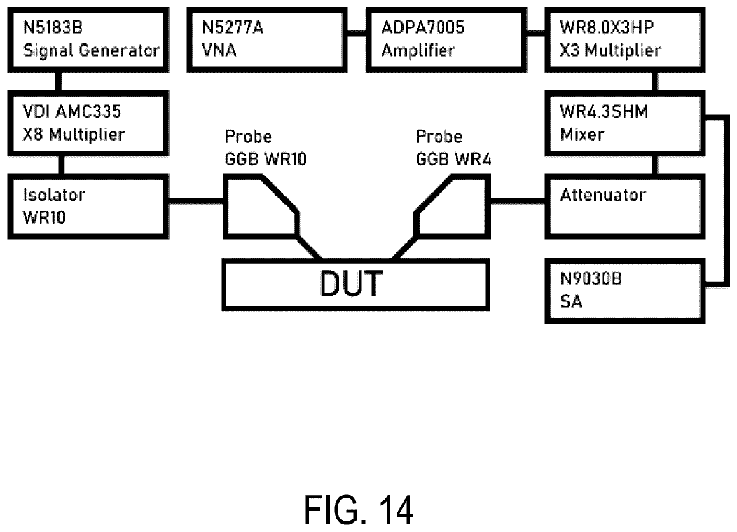

Measurements were made on the bias-feedback frequency doubler with a 3-V supply through an output probe bias tee, supplying 14.4 mA of quiescent current on V_{CC}, while V_{SYS} is open and not implemented for this test structure. Because of the wide output bandwidth of the doubler, the measurement was split into two frequency ranges. FIG. 13 shows the power measurement setup at the higher D-band input range with the chip micrograph, while FIG. 14 shows the setup at the lower W-band input range. The setup is calibrated with a VDI PM5B power meter for the input source across its power range and the output detection. The output is measured by down-converting the output spectrum of the doubler to a spectrum analyzer. The detected narrow-band power is adjusted by using the power meter as the primary calibration reference.

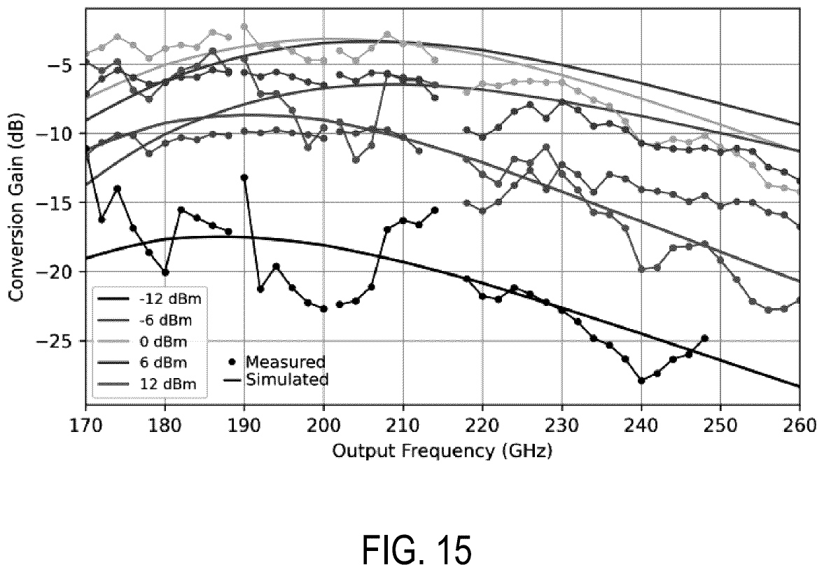

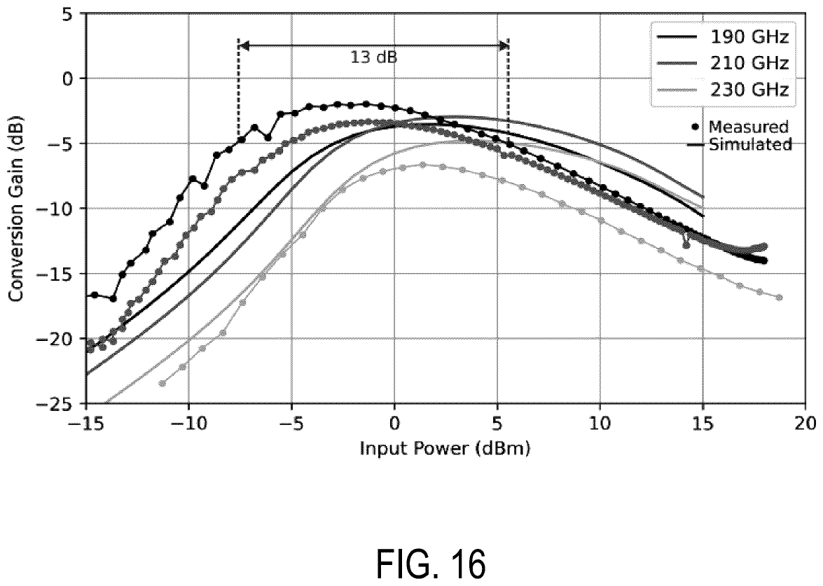

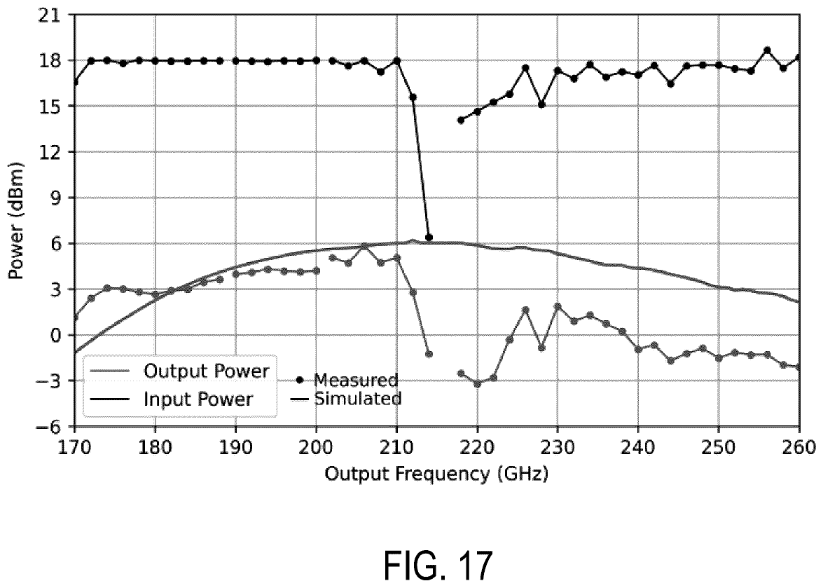

The doubler's output gain is measured across a range of input powers across frequency with results in agreement with simulation as shown in FIG. 15. In FIG. 16, the frequency doubler exhibits the predicted gain flatness across a wide range of input powers. At 190 GHz, the doubler has 13.0 dB of 3-dB input power range, where the gain is within 3 dB of the peak gain at −2.0 dB, exemplifying the primary effect of adapting the bias of the doubler. FIG. 17 shows that the saturated output power relationship is close to simulation, despite being limited by equipment input power. The gain bandwidth with a 12 dBm input is 170-218 GHz. The peak output power is 5.8 dBm, an equivalent 1.2 Vpp on 50 Ω, at 206 GHz with 18.0 dBm of input power. The doubler delivers more than −3.3 dBm over 170-260 GHz.

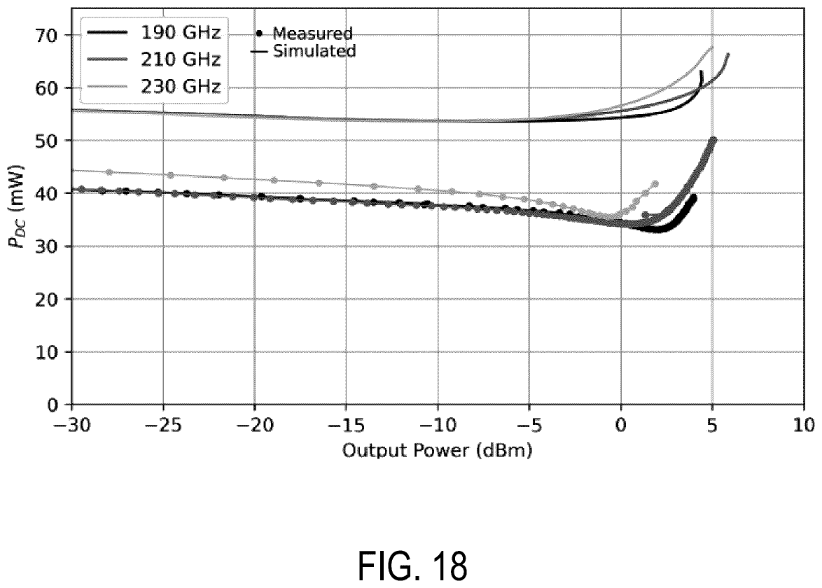

FIG. 18 shows a trend of flatness in power consumption, indicating that the bias feedback is controlling bias current across a wide range of input powers, despite an offset from simulation. The target quiescent current was 18.8 mA while the measured current was 14.4 mA. The current discrepancy could be due to poor tolerance of the small, high sheet resistance polysilicon resistors in the design, in addition to some VBE variation. With peak output power at 206 GHz, the collector efficiency is 7.2%, while DC consumption is 53 mW.

As shown by Table 2, the bias adaptation in this work enables higher output power over a wide input power range without significant sacrifice of other performance attributes.

TABLE 2

| Ref. | This Work | [6] | [7] | [8] | [9] | [10] |
|---|---|---|---|---|---|---|
| Technology | 90-mm SiGe | 55-mm SiGe | 130-nm SiGe | 130-nm SiGe | 90-nm SiGe | 45-nm SOI |
| | BiCMOS | BiCMOS | BiCMOS | BiCMOS | BiCMOS | CMOS |
| Type | Doubler + | Doubler + | Doubler + | Doubler | Doubler | Doubler |
| | Amplifier | Amplifier | Amplifier | | | |
| Output | 206 | 245 | 152 | 204 | 228 | 150 |
| Frequency (GHz) | | | | | | |
| BW [symbol] (GHz) | 170-218 ^{‡} | 220-260 | 138-170 | 165-230 | 200-245 | 135-160 |
| Peak Gain (dB) | −2.0 ^{§} | 10.9 | 4.9 | −8.6 | −15 | −3 |
| P [symbol] (dBm) | 5.8 | 5.5 | 5.6 | −2.6 | 2 | 3.5 |
| P [symbol] (mW) | 53 | 240 | 36 | 39 | 35 | 25 |
| Efficiency (%) | 7.2 | 9.5 | 10.9 | 1.4 | 4.5 | 9.0 |
| Area (mm²) | 0.0131 [symbol] 0.074 | 0.253 | 0.485 | 0.090 | 0.246 | 0.441 |
| 3-dB Gain Input | 13.0 § | 6 [symbol] | 9 [symbol] | >7 [symbol] | >6 [symbol] | 11 [symbol] |
| Range (dB) | | | | | | |

[symbol]

Estimated from plot.
^{†} Area without pads.
^{‡} Lower end limited by G-band measurement, with 12 dBm input.
^{§} At 190 GHz. [symbol]
indicates data missing or illegible when filed

A G-band frequency doubler in 90-nm SiGe BiCMOS technology with a novel resistive feedback adaptation is presented. With a peak gain of −2.0 dB measured at 190 GHz and a 13-dB input power range defined by the 3-dB gain variation, this doubler demonstrates the benefit of the adaptive biasing with no penalty in power consumption, area, or output power. The doubler delivers more than −3.3 dBm over 170-260 GHz, with a peak of 5.8 dBm. These results strongly support the potential for implementing efficient LO multiplier chains in adaptive transceivers that can take advantage of variable LO power.

### Terminology

Although this disclosure has been described in the context of certain embodiments and examples, it will be understood by those skilled in the art that the disclosure extends beyond the specifically disclosed embodiments to other alternative embodiments and/or uses and obvious modifications and equivalents thereof. In addition, while several variations of the embodiments of the disclosure have been shown and described in detail, other modifications, which are within the scope of this disclosure, will be readily apparent to those of skill in the art. It is also contemplated that various combinations or sub-combinations of the specific features and aspects of the embodiments may be made and still fall within the scope of the disclosure. For example, features described above in connection with one embodiment can be used with a different embodiment described herein and the combination still fall within the scope of the disclosure. It should be understood that various features and aspects of the disclosed embodiments can be combined with, or substituted for, one another in order to form varying modes of the embodiments of the disclosure. Thus, it is intended that the scope of the disclosure herein should not be limited by the particular embodiments described above. Accordingly, unless otherwise stated, or unless clearly incompatible, each embodiment of this invention may include, additional to its essential features described herein, one or more features as described herein from each other embodiment of the invention disclosed herein.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, 0.1 degree, or otherwise.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

What is claimed is:

1. A frequency conversion system, comprising:
a conversion circuit configured to receive an input signal and a bias signal, and to generate an output signal at a different frequency than the input signal, the output signal having an output power;
a power detection circuit electrically coupled to the conversion circuit and configured to produce a control signal based on at least one characteristic of the input signal or the output signal; and
a feedback control circuit configured to adjust the bias signal based on the control signal,
wherein the feedback control circuit dynamically varies the bias signal such that the output power of the conversion circuit is regulated by decreasing a conversion gain of the conversion circuit when the output power increases and by increasing the conversion gain of the conversion circuit when the output power decreases.

2. The frequency conversion system of claim 1, wherein the conversion circuit comprises a pair of transistors configured in a push-pull topology, wherein the power detection circuit comprises a transistor having an emitter coupled to collectors of the pair of transistors, and a bias resistor connected between a collector and a base of the transistor; and wherein the feedback control circuit comprises a feedback resistor connected to the collectors of the pair of transistors and an inductor coupled to an input port of the conversion circuit.

3. The frequency conversion system of claim 1, wherein the power detection circuit is configured to modulate the control signal based on at least one characteristic of the input signal, wherein the at least one characteristic of the input signal comprises input power level, input frequency, input amplitude, or input phase.

4. The frequency conversion system of claim 1, wherein the power detection circuit is configured to modulate the control signal based on at least one characteristic of the output signal, wherein the at least one characteristic of the output signal comprises output power level, output frequency, output amplitude, or output phase.

5. The frequency conversion system of claim 1, wherein the power detection circuit comprises a transistor configured to detect changes in the output power of the conversion circuit and to generate the control signal in response to the changes in the output power.

6. The frequency conversion system of claim 1, wherein the feedback control circuit is configured to maintain a substantially linear relationship between input signal power and the output signal power over a defined operating range.

7. The frequency conversion system of claim 1, wherein the feedback control circuit is configured to dynamically adjust the bias signal in real time based on instantaneous variations in the output power.

8. The frequency conversion system of claim 1, wherein the conversion circuit further comprises a pair of transistors arranged to generate a fourth harmonic of the input signal in a push-pull multiplier stage.

9. The frequency conversion system of claim 1, wherein the conversion circuit includes a pair of transistors in a push-pull topology, and wherein the bias signal is applied to bases of the pair of transistors to regulate conduction cycles and control conversion gain.

10. The frequency conversion system of claim 1, wherein the conversion circuit comprises at least one of a Gilbert cell topology, a differential pair topology, a push-push topology, a cascode amplifier topology, a cross-coupled transistor pair topology, a common-base amplifier topology, a common-emitter amplifier topology, a single-ended resonant tank topology, a differential amplifier topology, a distributed amplifier topology, or a phase-locked loop (PLL) topology.

11. A method of adaptively controlling a bias signal in a frequency multiplier circuit, the method comprising:
receiving, by a feedback control circuit, a control signal from a power detection circuit, wherein the control signal is based on at least one characteristic of an input signal or an output signal of the frequency conversion circuit;
generating, by the feedback control circuit, a dynamically adjustable bias signal in response to the control signal; and
applying the bias signal to the frequency conversion circuit, wherein the bias signal:
decreases in response to an increase in output power of the frequency conversion circuit, thereby reducing power consumption and gain variation; and
increases in response to a decrease in output power of the frequency conversion circuit, thereby maintaining a stable frequency conversion gain.

12. The method of claim 11, wherein the control signal is generated by detecting a rectified current component in the frequency conversion circuit, the rectified current component being indicative of output power variations.

13. The method of claim 11, wherein the feedback control circuit comprises a feedback resistor connected between a collector node of the frequency conversion circuit and a bias node, the feedback resistor adapting a conduction cycle of the multiplier transistors in response to changes in output power.

14. The method of claim 11, wherein the feedback control circuit regulates the bias signal to maintain a substantially constant transconductance in the frequency conversion circuit across a range of input power levels.

15. The method of claim 11, wherein the power detection circuit comprises a transistor configured in a common-base topology, the transistor generating the control signal based on variations in collector current from the frequency conversion circuit.

16. A feedback control circuit for a frequency conversion system, comprising:
a control input node configured to receive a control signal from a power detection circuit, the control signal being indicative of at least one characteristic of an input signal or an output signal of a frequency multiplier circuit;
a bias generation module configured to generate a dynamically adjustable bias signal in response to the control signal; and
a bias output node configured to provide the dynamically adjustable bias signal to the frequency multiplier circuit,
wherein the bias generation module is configured to reduce the bias signal in response to an increase in output power of the frequency multiplier circuit to compensate for gain variation and reduce power consumption, and wherein the bias generation module is configured to increase the bias signal in response to a decrease in output power of the frequency multiplier circuit to maintain a substantially stable frequency conversion gain across varying operating conditions.

17. The feedback control circuit of claim 16, wherein the bias generation module comprises a feedback resistor coupled between a collector node of the frequency multiplier circuit and a bias node, the feedback resistor being configured to adjust the conduction cycle of the multiplier transistors in response to variations in the control signal.

18. The feedback control circuit of claim 16, wherein the control signal is generated based on a rectified current component detected in the frequency multiplier circuit, the rectified current being indicative of output power variations.

19. The feedback control circuit of claim 16, wherein the bias generation module is configured to adjust the bias signal in real time to maintain a substantially linear relationship between input signal power and output signal power over a dynamic operating range.
